(19) United States
(12) Patent Application Publication
(10) Pub. No.: US 2025/0318356 A1
(43) Pub. Date: Oct. 9, 2025

(54) LIGHT-EMITTING ELEMENT AND METHOD FOR MANUFACTURING LIGHT-EMITTING ELEMENT

(71) Applicant: SHARP DISPLAY TECHNOLOGY CORPORATION, Kameyama City, Mie (JP)

(72) Inventor: YOSHIHIRO UETA, Sakai City, Osaka (JP)

(21) Appl. No.: 18/865,677

(22) PCT Filed: Jul. 5, 2022
(86) PCT No.: PCT/JP2022/026664

§ 371 Date: Nov. 13, 2024

(51) Int. Cl. H10K 50/115

(52) U.S. Cl. CPC H10K 50/115

(57) ABSTRACT

A charge function layer includes a first metal particle located on an electrode side of the charge function layer and a second metal particle located at a location separated from the first metal particle at a distance of 5 nm or less, and the second metal particle has a portion located closer to a light-emitting layer than a lower end of the first metal particle.

### TECHNICAL FIELD

The disclosure relates to a light-emitting element and a method for manufacturing a light-emitting element.

### BACKGROUND ART

PTL 1 discloses a light-emitting element in which a layer between a light-emitting layer and an electrode is a mixed film of a metal oxide or a metal halide and a metal.

### CITATION LIST

### Patent Literature

PTL 1: JP H11-111461 A

### SUMMARY

### Technical Problem

In the related art, electrical characteristics of a light-emitting element vary greatly each time the light-emitting element is electrified.

### Solution to Problem

A light-emitting element according to one aspect of the disclosure includes a light-emitting layer, an electrode, and a charge function layer located between the light-emitting layer and the electrode, in which the charge function layer includes a first metal particle located on the electrode side of the charge function layer, and a second metal particle positioned at a location separated from the first metal particle at a distance of 5 nm or less, and the second metal particle has a portion located closer to the light-emitting layer than a lower end of the first metal particle.

### Advantageous Effects of Disclosure

According to one aspect of the disclosure, it is possible to suppress variations in electrical characteristics of a light-emitting element each time the light-emitting element is electrified.

### BRIEF DESCRIPTION OF DRAWINGS

FIG. 1 is a first cross-sectional view illustrating a schematic configuration of a light-emitting element according to a first embodiment of the disclosure.

FIG. 2 is a diagram illustrating the movement of charges in a charge function layer in the light-emitting element according to the first embodiment of the disclosure.

FIG. 3 is a diagram illustrating the movement of charges in a charge function layer in a comparison element A.

FIG. 4 is a second cross-sectional view illustrating a schematic configuration of the light-emitting element according to the first embodiment of the disclosure.

FIG. 5 illustrates an example of a cross-sectional transmission electron microscope (TEM) image of the light-emitting element according to the first embodiment of the disclosure.

FIG. 6 is a graph showing voltage-current density characteristics for each electrification in each of the light-emitting elements according to the first embodiment of the disclosure and the comparison element A.

FIG. 7 is a diagram illustrating a method of manufacturing the light-emitting element according to the first embodiment of the disclosure.

FIG. 8 is a first cross-sectional view illustrating a modified example of a schematic configuration of the light-emitting element according to the first embodiment of the disclosure.

FIG. 9 is a diagram illustrating a modified example of a method of manufacturing the light-emitting element according to the first embodiment of the disclosure.

FIG. 10 is a diagram illustrating a method of manufacturing light-emitting elements according to second and third embodiments of the disclosure.

FIG. 11 is a diagram illustrating a first example of a metal structure.

FIG. 12 is a diagram illustrating a second example of a metal structure.

FIG. 13 is a first cross-sectional view illustrating a schematic configuration of another light-emitting element according to an embodiment of the disclosure.

FIG. 14 illustrates an example of an element map of the light-emitting element according to the first embodiment of the disclosure.

### DESCRIPTION OF EMBODIMENTS

Embodiments for implementing the disclosure will be described. For convenience of description, members having the same functions as members described earlier may be denoted by the same reference numerals and signs, and the description thereof will not be repeated.

### First Embodiment

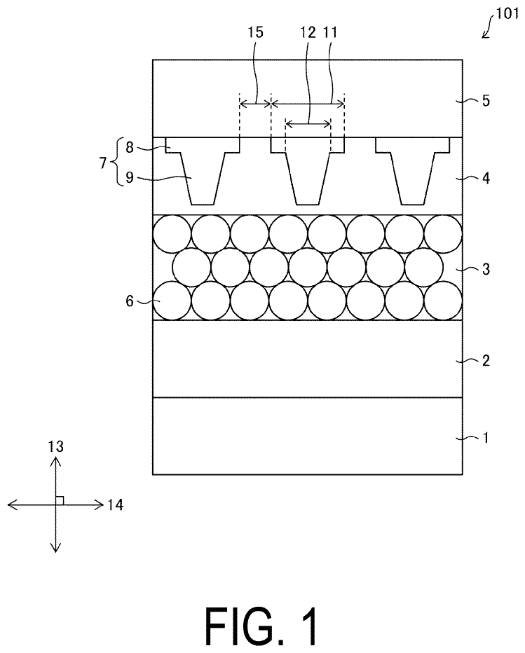

FIG. 1 is a first cross-sectional view illustrating a schematic configuration of a light-emitting element 101 according to a first embodiment of the disclosure. The light-emitting element 101 includes an electrode 1, a charge function layer 2, a light-emitting layer 3, a charge function layer 4, and an electrode 5. The light-emitting element 101 emits light by a current flowing between the electrode 1 and the electrode 5.

The charge function layer 2 includes (1) at least one of a hole injection layer and a hole transport layer, and (2) at least one of an electron injection layer and an electron transport layer. The charge function layer 4 includes the other of (1) and (2).

The light-emitting layer 3 may be a so-called quantum dot light-emitting diode (QLED) layer that emits light by quantum dots 6, but is not limited thereto, and may also be a so-called organic light-emitting diode (OLED) layer.

The charge function layer 4 is located between the light-emitting layer 3 and the electrode 5. The charge function layer 4 includes at least one metal structure 7. The metal structure 7 includes a first conductor portion 8 and a second conductor portion 9. The first conductor portion 8 is located on the electrode 5 side of the charge function layer 4. The second conductor portion 9 protrudes from the first conductor portion 8 toward the light-emitting layer 3. The metal structure 7 is electrically connected to the electrode 5. The material of the metal structure 7 is not particularly limited as long as it is a metal having electrical conductivity. Although the shape of the metal structure 7 is illustrated as a wedge shape in FIG. 1, this is merely a typical example and the shape of the metal structure 7 is not limited to a wedge shape.

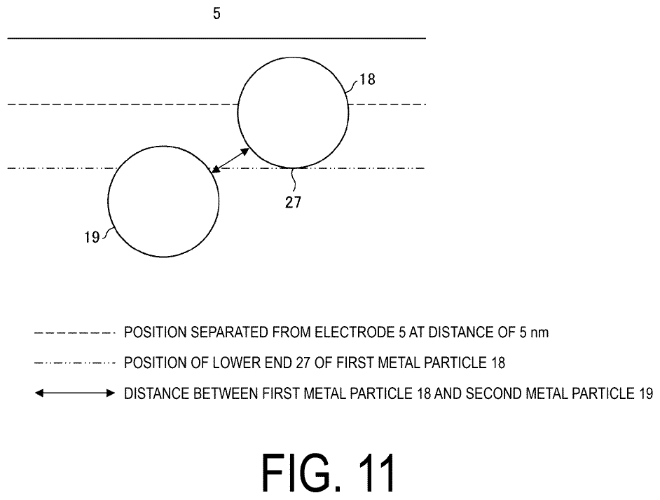

FIG. 11 is a diagram illustrating a first example of a metal structure 7. FIG. 11 may be interpreted as an enlarged view of the metal structure 7.

The charge function layer 4 may include a metal structure 7 as follows. The metal structure 7 includes first metal particles 18 and second metal particles 19. Specifically, the metal structure 7 includes the first metal particles 18 located on the electrode 5 side, and the second metal particles 19 positioned at locations separated from the first metal particles 18 by a distance of 5 nm or less. Furthermore, the second metal particle 19 has a portion located closer to the light-emitting layer 3 than a lower end 27 of the first metal particle 18. Regarding a distance between the first metal particle 18 and the second metal particle 19, the shortest distance between the two particles may be used. The shape of each of the first metal particle 18 and the second metal particle 19 is not particularly limited.

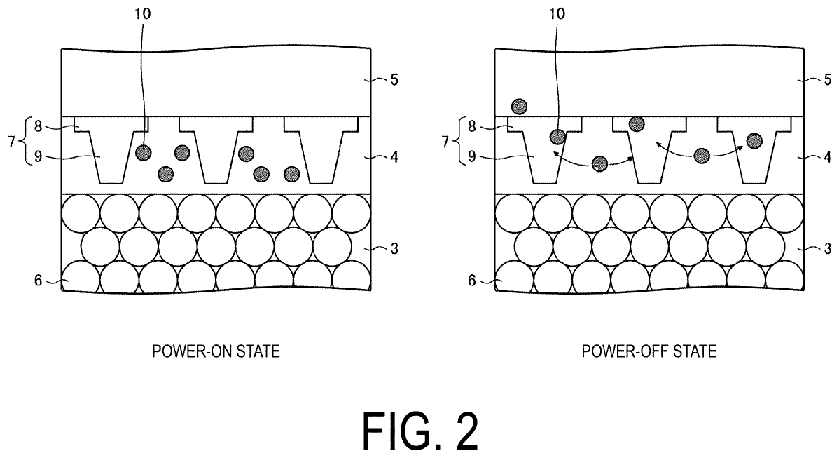

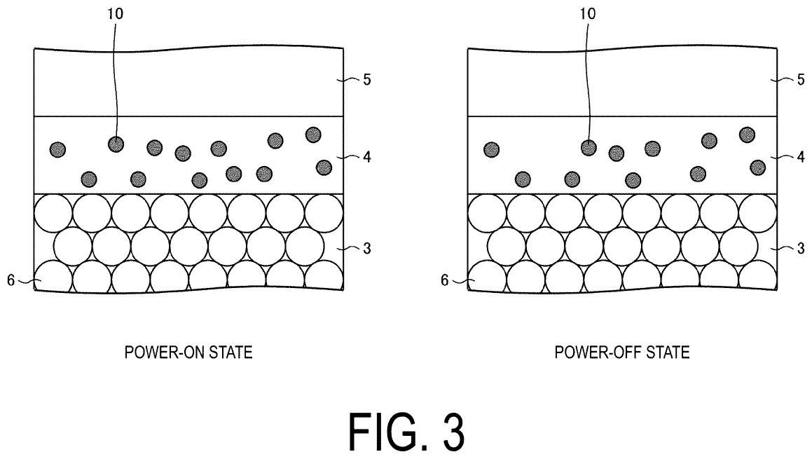

FIG. 2 is a diagram illustrating the movement of charges 10 in the charge function layer 4 in the light-emitting element 101. FIG. 3 is a diagram illustrating the movement of charges 10 in a charge function layer 4 in a comparison element A. The configuration of the comparison element A differs from the configuration of the light-emitting element 101 in that the charge function layer 4 does not include a metal structure 7, but is the same as the configuration of the light-emitting element 101 in the other respects. The charges 10 are holes with the charge function layer 4 of case (1) described above, and are electrons with the charge function layer 4 of case (2) described above.

In the light-emitting element 101, when the light-emitting element 101 is in a power-off state, most of a large number of charges 10 accumulated in the charge function layer 4 are guided to the electrode 5 via the metal structure 7. As a result, the amount of charges 10 accumulated in the charge function layer 4 is stably small each time the light-emitting element 101 is powered on. Thus, there is little variation in the electrical characteristics of the light-emitting element 101 each time the light-emitting element 101 is electrified.

In the comparison element A, when the comparison element A is in a power-off state, most of a large number of charges 10 accumulated in the charge function layer 4 continuously remain in the charge function layer 4. As a result, the amount of charges 10 accumulated in the charge function layer 4 varies greatly each time the comparison element A is powered on. Thus, there is a large variation in the electrical characteristics of the comparison element A each time the comparison element A is electrified.

The first conductor portion 8 and the second conductor portion 9 may include the same metal element. For example, in the metal structure 7 illustrated in FIG. 11, the first metal particle 18 and the second metal particle 19 may include the same metal element. A width 11 of the first conductor portion 8 may be larger than a width 12 of the second conductor portion 9. The “width” of each of the first conductor portion 8 and the second conductor portion 9 is defined as a dimension in a certain direction 14 perpendicular to a thickness direction 13 of the charge function layer 4. When the width of each of the first conductor portion 8 and the second conductor portion 9 is not constant, the maximum value of the width may be noted. FIG. 1 illustrates an example in which the width 11 of the first conductor portion 8 is constant and the width 12 of the second conductor portion 9 is not constant along the thickness direction 13 of the charge function layer 4, and the width 11 of the first conductor portion 8 is larger than the maximum width of the second conductor portion 9. The metal structure 7 may be separated from the light-emitting layer 3. Furthermore, the width of the second conductor portion 9 may be smaller than the width of the first conductor portion 8. With the above-described configuration, it is possible to suppress capacitance generated between the second conductor portion 9 and the light-emitting layer 3.

The metal structure 7 may be in contact with the electrode 5. On the other hand, considering that charges 10 can be guided from the metal structure 7 to the electrode 5 by a tunnel effect, it is not essential that the metal structure 7 and the electrode 5 are in contact with each other, and the metal structure 7 and the electrode 5 may be configured such that they are not in contact with each other but are extremely close to each other (for example, a distance of less than 5 nm). The position of the first conductor portion 8 on the “side of the electrode 5” in the charge function layer 4 encompasses a configuration in which the metal structure 7 and the electrode 5 are in contact with each other, and a configuration in which the metal structure 7 and the electrode 5 are not in contact with each other but are extremely close to each other. For example, regarding the metal structure 7 illustrated in FIG. 11, the first metal particles 18 may be in contact with the electrode 5, or the first metal particles 18 and the electrode 5 may be configured such that they are not in contact with each other but are extremely close to each other (for example, a distance of less than 5 nm). The position of the first metal particles 18 on the “side of the electrode 5” in the charge function layer 4 encompasses a configuration in which the first metal particles 18 and the electrode 5 are in contact with each other, and a configuration in which the first metal particles 18 and the electrode 5 are not in contact with each other but are extremely close to each other.

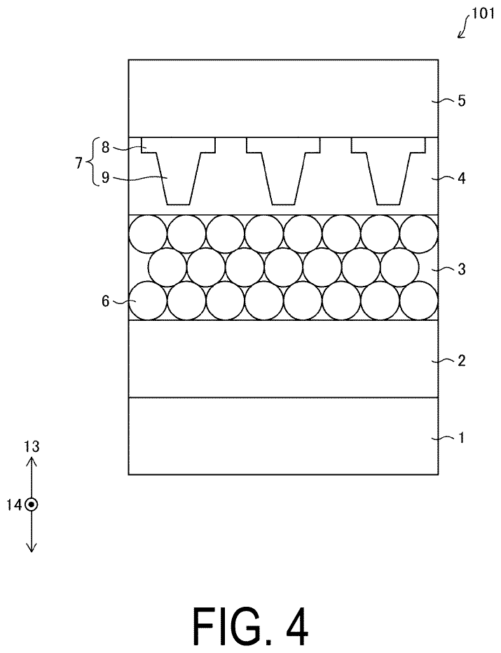

FIG. 4 is a second cross-sectional view illustrating a schematic configuration of the light-emitting element 101 according to the first embodiment of the disclosure. The surface of the charge function layer 4 illustrated in FIG. 1 is assumed to be a first cross-section, and the surface of the charge function layer 4 illustrated in FIG. 4 is assumed to be a second cross-section. In other words, the charge function layer 4 includes the first cross-section and the second cross-section. The first cross-section and the second cross-section are each along the thickness direction 13 of the charge function layer 4. The second cross-section is perpendicular to the first cross-section.

The charge function layer 4 has a plurality of metal structures 7. At least two of the plurality of metal structures 7 are present in the first cross-section. At least two of the plurality of metal structures 7 are also present in the second cross-section. This means that the plurality of metal structures 7 are disposed two-dimensionally when viewed from above the charge function layer 4.

A distance between two adjacent metal structures among the plurality of metal structures 7 may be 100 nm or more. In each of the plurality of metal structures 7, the width 11 of the first conductor portion 8 may be 100 nm or less, and the width of the second conductor portion 9 may be 40 nm or less. When the width of each of the first conductor portion 8 and the second conductor portion 9 is not constant, the maximum value of the width may be noted. A distance between two adjacent metal structures among the plurality of metal structures 7 may be a distance 15 between portions where the two adjacent metal structures are closest to each other in a direction perpendicular to the thickness direction 13 of the charge function layer 4.

The charge function layer 4 includes a plurality of metal nanoparticles, and a particle size distribution of the plurality of metal nanoparticles may have a median value of 4 nm or more and 6 nm or less, a minimum value of 1 nm or more, and a maximum value of 30 nm or less. Each of the plurality of metal nanoparticles may be any of a Group 1 element, a Group 4 element, a Group 6 element, and a Group 12 element. Specific examples of the materials for the metal nanoparticles include zinc oxide (ZnO), magnesium zinc oxide (MgZnO), titanium oxide (TiO₂), strontium oxide (SrTiO₃), and the like.

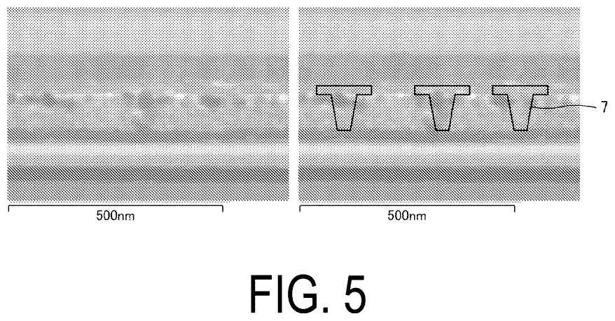

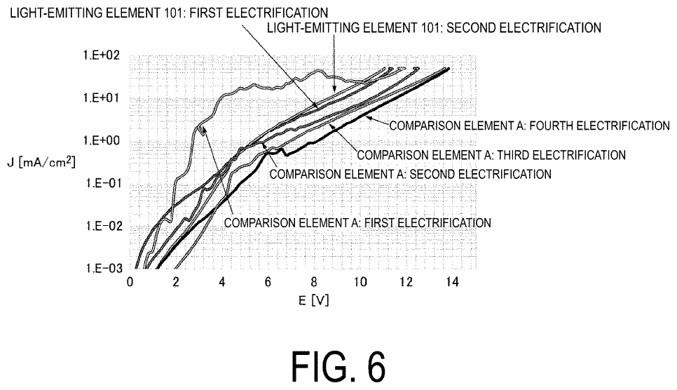

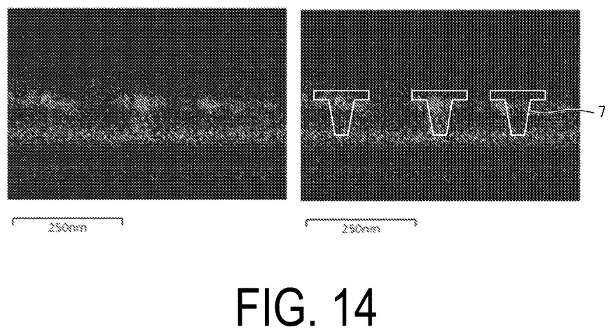

FIG. 5 illustrates an example of a cross-sectional transmission electron microscope (TEM) image of the light-emitting element 101. FIG. 14 illustrates an example of an element map of the light-emitting element 101. The surface of the light-emitting element 101 illustrated in FIGS. 5 and 14 corresponds to the surface of the light-emitting element 101 illustrated in FIG. 1. The image illustrated in FIG. 14 is an element map, and a structure in a depth direction can also be confirmed. For this reason, it is also acceptable for some of the metal structures 7 to appear to be in contact with the light-emitting layer 3 in the depth direction. FIG. 6 is a graph showing voltage-current density characteristics for each electrification in each of the light-emitting element 101 and the comparison element A.

According to FIG. 6, the light-emitting element 101 shows substantially the same voltage-current density characteristics for the first and second electrifications, whereas the comparison element A shows voltage-current density characteristics that fluctuate in a stepwise manner from the first electrification to the fourth electrification. External quantum efficiency (EQE) is approximately 7% for the light-emitting element 101 and 3% or less for the comparison element A at the fourth electrification. At the first electrification of the comparison element A, the EQE of the comparison element A is 1% or less. From these results, it can be understood that the light-emitting element 101 has more stable electrical characteristics and an improved EQE than those of the comparison element A.

It can be understood from FIGS. 5 and 14 and FIG. 6 that in the comparison element A, charges 10 are accumulated by the electrification of the comparison element A, and the accumulated charges 10 are not released for a long period of time (at least several minutes). From the structure of the comparison element A, it is considered that the charges 10 are accumulated in a capacitor constituted by the light-emitting layer 3, the charge function layer 4, and the electrode 5. On the other hand, in the light-emitting element 101, electrical characteristics are stable regardless of the number of times of electrification, and thus it is considered that the amount of charges 10 accumulated in the capacitor is small, and the small amount of accumulated charges 10 is also rapidly released.

Specifically, the following can be read from FIG. 6. There is a history of leaving the comparison element A for approximately five minutes in an unelectrified state between “Comparison element A: first electrification” and “Comparison element A: second electrification”. The reason for leaving the comparison element A in an unelectrified state is that, since a normal capacitor discharges in a short period of time, it is predicted that leaving it for 5 minutes in an unelectrified state would result in the same curve for the “Comparison element A: first electrification” and the “Comparison element A: second electrification”. However, experimental results contrary to this prediction are obtained, indicating that the accumulation of the charges 10 in the comparison element A is not caused by a general mechanism such as a parallel plate capacitor, but caused by charges 10 captured by an organic compound including nanoparticles in the charge function layer 4 and ligands coordinated to the nanoparticles. Thus, once charges 10 are accumulated in the comparison element A, it is considered that the charges 10 will not be released for at least several minutes. “Comparison element A: third electrification” and “Comparison element A: fourth electrification” are results of electrification performed repeatedly and consecutively without any interval, and it is considered that (X) charges 10 are captured up to a possible upper limit, resulting in no change in the voltage-current density characteristics, or that (Y) the state of the charge function layer 4 is changed due to repeated electrification and almost no charge 10 is captured. Furthermore, when the comparison element A is remeasured the next day or later, the voltage-current density characteristics change depending on the number of times of electrification, and thus it can be understood that the above phenomenon is a reversible phenomenon. On the other hand, in the light-emitting element 101, voltage-current density characteristics close to those of the comparison element A which are obtained by a plurality of consecutive electrifications are obtained in the first electrification, and thus it is considered that the phenomenon of the comparison element A is caused by (Y).

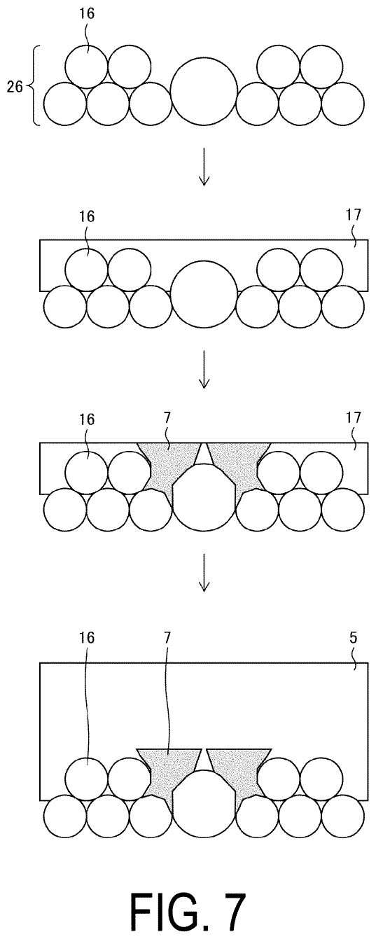

FIG. 7 is a diagram illustrating a method of manufacturing the light-emitting element 101. The method of manufacturing the light-emitting element 101 includes the following processes (A) to (C).

(A) A charge function layer 26 of the light-emitting element 101 including a metal oxide 16 is formed.

(B) A base metal film 17 is formed on the charge function layer 26.

(C) A metal structure 7 of the light-emitting element 101 is formed of a metal obtained by reducing the metal oxide 16 using the base metal film 17. For example, with respect to the metal structure 7 illustrated in FIG. 11, the first metal particles 18 and the second metal particles 19 of the light-emitting element 101 may be formed of the metal obtained by reducing the metal oxide 16 using the base metal film 17.

The metal oxide 16 may correspond to the plurality of metal nanoparticles described above. The light-emitting element 101 has a structure in which a conductive metal structure 7 is introduced into the charge function layer 26 based on a general light-emitting element that emits light using quantum dots 6. A method of manufacturing the light-emitting layer 3 and the layers below the light-emitting layer 3 is within the scope of well-known technology, and thus a detailed description thereof will be omitted here.

The charge function layer 26 is formed by applying ZnO nanoparticles (an example of metal nanoparticles, a component of the metal oxide 16) or by forming a continuous ZnO film with a thickness of approximately 40 nm by, for example, a sputtering method or a sol-gel method. Here, an example in which the charge function layer 26 is formed of ZnO nanoparticles is described.

When the charge function layer 26 is formed by applying ZnO nanoparticles, a colloidal solution in which the median value of particle size distribution of the ZnO nanoparticles included in the colloidal solution is closer to the minimum value than the maximum value is used. For example, a difference between the median value of the particle size distribution of the ZnO nanoparticles in the colloidal solution and the maximum value of the distribution may be a maximum of approximately 100 nm. The charge function layer 26 can be formed by applying the colloidal solution and performing heat treating thereon at approximately 100° C. for 15 minutes. At this time, localized irregularities are generated on the surface of the charge function layer 26 due to the large-diameter ZnO nanoparticles included in the colloidal solution. The irregularities are generated selectively around the large-diameter ZnO nanoparticles. Regions of the charge function layer 26 other than the irregularities are maintained flat. Next, the base metal film 17 of such as Al is formed to a thickness of approximately 10 nm by a general method such as vacuum deposition, and heat treatment is performed for 10 minutes at approximately 100° C. while maintaining a vacuum state. Since base metals such as Al are easily oxidized themselves, they reduce other oxides that they come into contact with. The base metal film 17 reduces ZnO included in the charge function layer 26 to precipitate Zn. At this time, in the regions where the irregularities are formed, Zn precipitates selectively because the contact area with the base metal film 17 is large, and Zn precipitates by tracing intervals between the large-diameter ZnO nanoparticles and adjacent ZnO nanoparticles. Thereby, Zn is formed as a metal structure 7 (for example, the first metal particles 18 and the second metal particles 19 for the metal structure 7 illustrated in FIG. 11) in the region where the irregularities are formed. After the heat treatment, Al or the like is evaporated to a predetermined thickness on the charge function layer 4 having the metal structure 7 to form the electrode 5. At least a part of the electrode 5 of the light-emitting element 101 may be formed by the base metal film 17. The irregularities may be gaps resulting from aggregation of nanoparticles in addition to being formed by large-diameter nanoparticles.

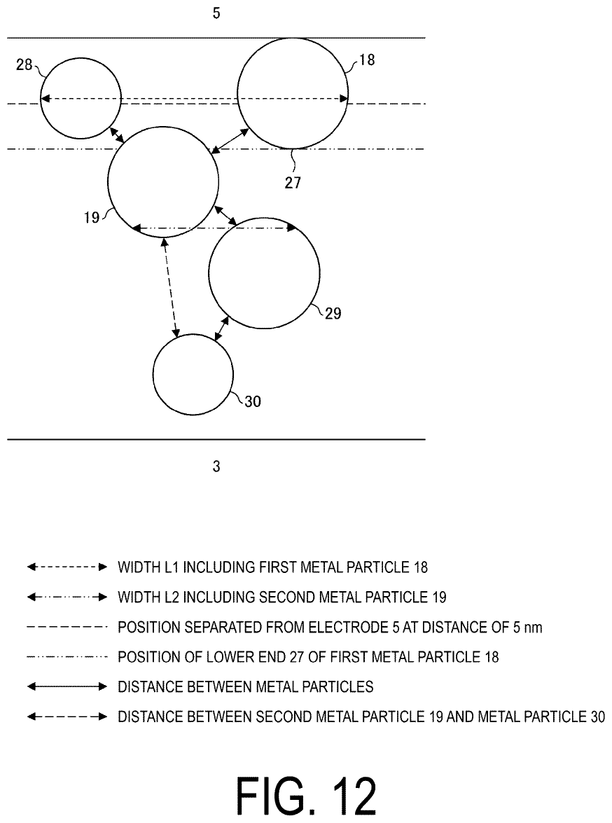

FIG. 12 is a diagram illustrating a second example of a metal structure 7. FIG. 12 may be interpreted as an enlarged view of the metal structure 7.

The charge function layer 4 includes a metal structure 7 including a plurality of metal particles including first metal particles 18 and second metal particles 19. The metal structure 7 may include metal particles in addition to the first metal particles 18 and the second metal particles 19. In this case, the metal structure 7 is a structure including metal particles that are connected to each other at a distance of 5 nm or less. For example, when an inter-particle distance between two metal particles is 0 nm, the two metal particles can be regarded as one metal particle.

A specific example of the metal structure 7 is illustrated in FIG. 12. The metal structure 7 illustrated in FIG. 12 includes metal particle 28, metal particles 29, and metal particles 30 in addition to the first metal particle 18 and the second metal particle 19. An inter-particle distance between the metal particle 28 and the second metal particle 19, an inter-particle distance between the metal particle 29 and the second metal particle 19, and an inter-particle distance between the metal particle 29 and the metal particle 30 are each 5 nm or less.

A maximum value of the distance between any two adjacent metal particles among the plurality of metal particles may be 5 nm or less. By setting the inter-particle distance to 5 nm or less, charges around the metal particles can be guided to the electrode 5 via the metal particles by a tunnel effect.

For example, with regard to charges around the metal particles 30, even when an inter-particle distance between the metal particle 30 and the second metal particle 19 is 5 nm or more, the charges can be guided to the electrode 5 via the metal particles 29, the second metal particles 19, and the first metal particles 18 by going through the metal particles 29.

In addition, since the metal particles 28 are located within 5 nm from the electrode 5 in the thickness direction, they may be regarded as first metal particles.

According to FIG. 12, with regard to the width of the metal structure 7, a width L2 including the second metal particle 19 is smaller than a width L1 including the first metal particle 18. Specifically, a certain direction 14 perpendicular to a thickness direction 13 including the first metal particles 18 is compared with a certain direction 14 perpendicular to a thickness direction 13 including the second metal particles 19. When the above-mentioned widths are not constant, the maximum width of the widths may be noted.

A specific example is illustrated in FIG. 12. The metal structure 7 illustrated in FIG. 12 includes the metal particles 28, the metal particles 29, and the metal particles 30 in addition to the first metal particles 18 and the second metal particles 19. The width L1 including the first metal particle 18 is the maximum width L1 in the certain direction 14 perpendicular to the thickness direction 13 including the first metal particle 18, and the width L2 including the second metal particle 19 is the maximum width L2 in the certain direction 14 perpendicular to the thickness direction 13 including the second metal particle 19.

The width L2 including the second metal particle 19 located closer to the light-emitting layer 3 than the width L1 including the first metal particle 18 is smaller than the width L1 including the first metal particle 18, making it easier for electrons reaching the light-emitting layer 3 to pass.

The metal particles may be separated from the light-emitting layer 3. For example, among the second metal particles 19 illustrated in FIG. 11 and the metal particles included in the metal structure 7 illustrated in FIG. 12, the metal particles 30 located closest to the light-emitting layer 3 may be separated from the light-emitting layer 3. Furthermore, the width L2 including the second metal particle 19 may be smaller than the width L1 including the first metal particle 18. With the above configuration, it is possible to suppress capacitance generated between the second metal particles 19 and the light-emitting layer 3.

In the process (C), for example, with respect to the metal structure 7 illustrated in FIG. 12, a plurality of metal particles including the first metal particles 18 and the second metal particles 19 of the light-emitting element 101 may be formed using a metal obtained by reducing the metal oxide 16 with the base metal film 17.

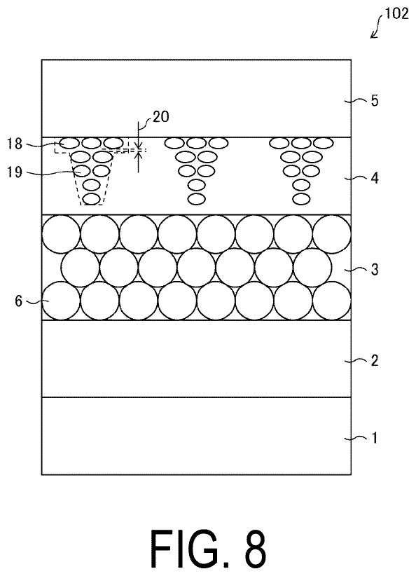

FIG. 8 is a first cross-sectional view illustrating a modified example of a schematic configuration of the light-emitting element 101 according to the first embodiment of the disclosure. A light-emitting element 102 illustrated in FIG. 8 is a modified example of the light-emitting element 101. The surface of the light-emitting element 102 illustrated in FIG. 8 corresponds to a first cross-section of the light-emitting element 101 illustrated in FIG. 1.

A configuration of the light-emitting element 102 differs from the configuration of the light-emitting element 101 in that the charge function layer 4 includes a plurality of first metal particles 18 and a plurality of second metal particles 19 instead of the metal structure 7, but is the same as the configuration of the light-emitting element 101 in the other respects.

Various technical matters related to the plurality of first metal particles 18 and the plurality of second metal particles 19 can be interpreted as corresponding to the various technical matters related to the first conductor portion 8 and the second conductor portion 9 on a one-to-one basis. That is, the following can be said.

The plurality of first metal particles 18 are located on the electrode 5 side of the charge function layer 4. The plurality of second metal particles 19 are located on the light-emitting layer 3 side with respect to the plurality of first metal particles 18. For all combinations of two adjacent particles among the plurality of first metal particles 18 and the plurality of second metal particles 19, a distance 20 between the two adjacent particles is 5 nm or less.

Any one of the plurality of first metal particles 18 (first metal particle 18) and any one of the plurality of second metal particles 19 (second metal particle 19) may include the same metal element. At least one of the plurality of first metal particles 18 (first metal particle 18) may be in contact with the electrode 5.

Each of the plurality of second metal particles 19 may be separated from the light-emitting layer 3. The charge function layer 4 includes a plurality of metal nanoparticles, and a particle size distribution of the plurality of metal nanoparticles may have a median value of 4 nm or more and 6 nm or less, a minimum value of 1 nm or more, and a maximum value of 30 nm or less. As in the light-emitting element 101, the light-emitting layer 3 may also emit light by quantum dots 6 in the light-emitting element 102.

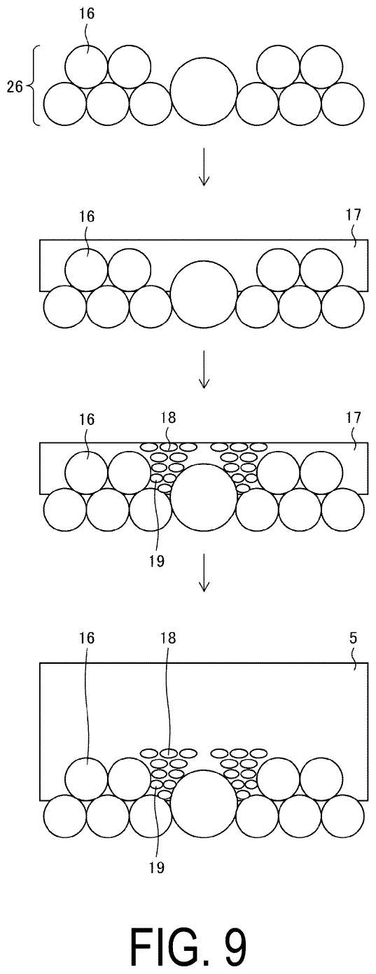

FIG. 9 is a diagram illustrating a method of manufacturing the light-emitting element 102. The method of manufacturing the light-emitting element 102 includes the following processes (D) to (F).

(D) The charge function layer 26 of the light-emitting element 102 including the metal oxide 16 is formed.

(E) The base metal film 17 is formed on the charge function layer 26.

(F) The plurality of first metal particles 18 and the plurality of second metal particles 19 of the light-emitting element 102 are formed of a metal obtained by reducing the metal oxide 16 using the base metal film 17.

At least a part of the electrode 5 of the light-emitting element 102 may be formed by the base metal film 17.

### Second Embodiment

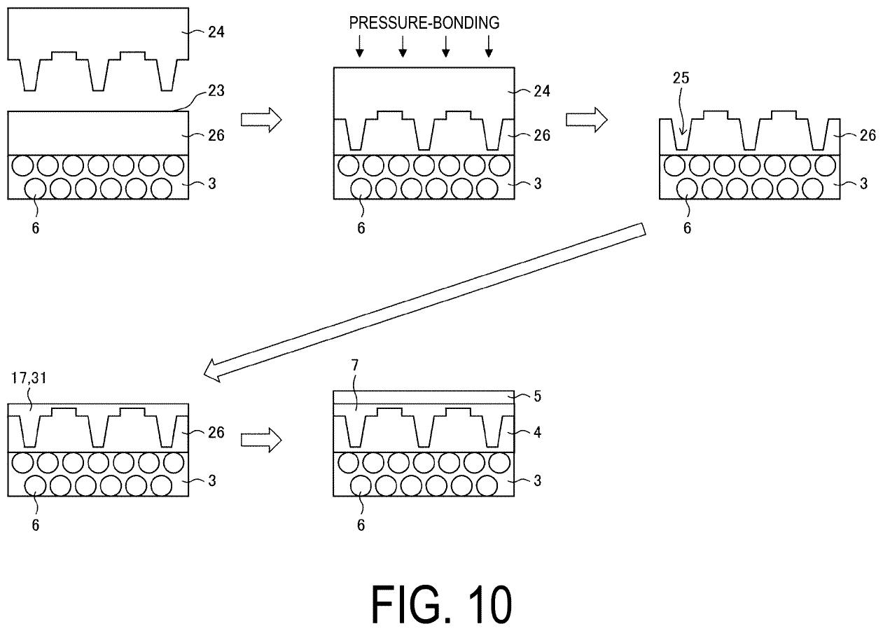

FIG. 10 is a diagram illustrating a method of manufacturing a light-emitting element 101 according to a second embodiment of the disclosure. The method of manufacturing the light-emitting element 101 according to the second embodiment of the disclosure differs from the method of manufacturing the light-emitting element 101 according to the first embodiment of the disclosure in the following respects, but is the same as the method of manufacturing the light-emitting element 101 according to the first embodiment of the disclosure in the other respects.

After a charge function layer 26 of the light-emitting element 101 including a metal oxide 16 (see FIG. 7) is formed, a nanoimprint mold 24 is pressure-bonded to a surface 23 of the charge function layer 26 on a side opposite to a light-emitting layer 3, and a recess 25 is formed on the surface 23 of the charge function layer 26 on a side opposite to the light-emitting layer 3. A base metal film 17 is formed on the charge function layer 26 such that the recess 25 is filled with the base metal film 17. The metal structure 7 of the light-emitting element 101 is formed of a metal obtained by reducing the metal oxide 16 using the base metal film 17.

The charge function layer 26 is formed by applying nanoparticles or sputtering. Thereafter, an intermediate of the light-emitting element 101 on which the layers up to the charge function layer 26 have been formed is loaded into a nanoimprinting device. The material of the charge function layer 26 is suitably a material including, for example, ZnO nanoparticles and having charge transport and/or charge injection properties. The shape of the nanoimprint mold 24 corresponds to the shape of the metal structure 7. The temperature of the intermediate of the light-emitting element 101 is increased to approximately 100° C. and the nanoimprint mold 24 is pressure-bonded to the surface 23 of the charge function layer 26 on a side opposite to the light-emitting layer 3, thereby forming a recess 25 in the charge function layer 26 into a shape obtained by inverting the shape of the metal structure 7. The intermediate of the light-emitting element 101 is taken out, the base metal film 17 of such as Al is formed thin by vacuum deposition, and processing up to the formation of an electrode 5 is performed by the same method as the method of manufacturing the light-emitting element 101 according to the first embodiment of the disclosure.

The light-emitting layer 3 is likely to deteriorate due to contact with a developer, or the like during patterning, but it is possible to perform processing for suppressing damage to the light-emitting layer 3 according to the methods of manufacturing the light-emitting element 101 according to the first and second embodiments of the disclosure. However, in order to prevent thermal deterioration in the process of heating the light-emitting layer 3, treatment is required to be performed at 150° C. or less for 15 minutes or less. When thermal deterioration is noted, it is possible to maintain the characteristics of the light-emitting element 101 even when the light-emitting layer 3 is exposed to the process of forming the metal structure 7.

In the method of manufacturing the light-emitting element 101 according to the second embodiment of the disclosure, the method of manufacturing the light-emitting element 102 according to the second embodiment of the disclosure can be realized by replacing the metal structure 7 with a plurality of first metal particles 18 and a plurality of second metal particles 19.

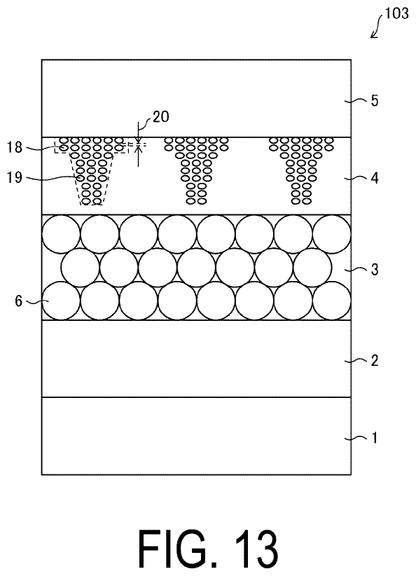

FIG. 13 is a first cross-sectional view illustrating a schematic configuration of another light-emitting element 103 according to an embodiment of the disclosure. The light-emitting element 103 illustrated in FIG. 13 has metal particles with particle sizes smaller than those of the light-emitting element 102 illustrated in FIG. 8. The light-emitting element 103 can be manufactured by the same method as the method of manufacturing the light-emitting element 102.

### Third Embodiment

In the content illustrated in FIG. 10, instead of the base metal film 17, a metal material 31 may be filled into the recess 25 to form first metal particles 18 and second metal particles 19 or a metal structure 7. Thereby, it is not necessary to apply reduction using the base metal film 17.

After a charge function layer 26 of a light-emitting element 101 is formed, a nanoimprint mold 24 is pressure-bonded to a surface 23 of the charge function layer 26 on a side opposite to a light-emitting layer 3, and the recess 25 is formed on the surface 23 of the charge function layer 26 on a side opposite to the light-emitting layer 3. The metal material 31 is formed on the charge function layer 26 so as to fill the recess 25 with the metal material 31. The first metal particles 18 and the second metal particles 19 or the metal structure 7 of the light-emitting element 101 are formed by the metal material 31.

The metal material 31 may be metal particle groups. In this case, since the metal material 31 is filled, it may be heated to several tens of degrees by itself, but the temperature may be raised to approximately 80° C. by radiation during deposition of the electrode 5. Thereby, the metal particle groups filled during the deposition of the electrode 5 may partially fuse with each other.

### Appendix

A comparison element B is considered. The comparison element B is an element in which the metal structure 7 of the light-emitting element 101 is replaced with an insulating material having the same shape as the metal structure 7. The method of manufacturing the comparison element B is the same as the method of manufacturing the light-emitting element 101 according to the second embodiment of the disclosure, except that an insulating polyvinylpyrrolidone (PVP) film is formed instead of the base metal film 17 by, for example, spin coating.

Although the comparison element B includes a member having the same shape as the metal structure 7, the electrical characteristics of the comparison element B vary each time the comparison element B is electrified. That is, the comparison element B shows electrical characteristics similar to those of the comparison element A described above. It is estimated that the comparison element B has poor ability to guide charges accumulated in the charge function layer 4 to the electrode 5 due to the replacement of the metal structure 7 with the insulating material.

### Supplement

A light-emitting element according to a first aspect of the disclosure includes a light-emitting layer, an electrode, and a charge function layer located between the light-emitting layer and the electrode, in which the charge function layer includes first metal particles located on the electrode side of the charge function layer, and second metal particles positioned at locations separated from the first metal particles at a distance of 5 nm or less, and the second metal particle has a portion located closer to the light-emitting layer than a lower end of the first metal particle.

A light-emitting element of a second aspect of the disclosure according to the first aspect further includes a metal structure including a plurality of metal particles including at least the first metal particles and the second metal particles, in which a maximum value of the distance between any two adjacent particles in the plurality of metal particles is 5 nm or less.

In a light-emitting element of a third aspect of the disclosure according to the second aspect, a width including the second metal particle in the metal structure is smaller than a width including the first metal particle.

In a light-emitting element of a fourth aspect of the disclosure according to the second or third aspect, the metal particles are separated from the light-emitting layer.

In a light-emitting element of a fifth aspect of the disclosure according to any one of the first to fourth aspects, the first metal particle and the second metal particle include the same metal element.

In a light-emitting element of a sixth aspect of the disclosure according to any one of the first to fifth aspects, the first metal particles are in contact with the electrode.

A light-emitting element of a seventh aspect 7 of the disclosure includes a light-emitting layer, an electrode, and a charge function layer located between the light-emitting layer and the electrode, in which the charge function layer includes at least one metal structure, and the metal structure includes a first conductor portion located on the electrode side of the charge function layer, and a second conductor portion protruding from the first conductor portion toward the light-emitting layer.

In a light-emitting element of an eighth aspect of the disclosure according to the seventh aspect, the first conductor portion and the second conductor portion include the same metal element.

In a light-emitting element of a ninth aspect of the disclosure according to the seventh or eighth aspect, a width of the first conductor portion is larger than a width of the second conductor portion.

In a light-emitting element of a tenth aspect of the disclosure according to any one of the seventh to ninth aspects, the metal structure is separated from the light-emitting layer.

In a light-emitting element of an eleventh aspect of the disclosure according to any one of the seventh to tenth aspects, the metal structure is in contact with the electrode.

In a light-emitting element of a twelfth aspect of the disclosure according to any one of the seventh to eleventh aspects, the charge function layer includes a plurality of metal structures, and includes a first cross-section along a thickness direction of the charge function layer and having at least two of the plurality of metal structures, and a second cross-section along the thickness direction of the charge function layer and perpendicular to the first cross-section and having at least two of the plurality of metal structures.

In a light-emitting element of a thirteenth aspect of the disclosure according to the twelfth aspect, a distance between two adjacent metal structures among the plurality of metal structures is 100 nm or more.

In a light-emitting element of a fourteenth aspect of the disclosure according to the thirteenth aspect, in each of the plurality of metal structures, the first conductor portion has a width of 100 nm or less, and the second conductor portion has a width of 40 nm or less.

In a light-emitting element of a fifteenth aspect of the disclosure according to any one of the first to fourteenth aspects, the charge function layer includes a plurality of metal nanoparticles, and a particle size distribution of the plurality of metal nanoparticles has a median value of 4 nm or more and 6 nm or less, a minimum value of 1 nm or more, and a maximum value of 30 nm or less.

In a light-emitting element of a sixteenth aspect of the disclosure according to the fifteenth aspect, each of the plurality of metal nanoparticles is any one of a Group 1 element, a Group 4 element, a Group 6 element, and a Group 12 element.

In a light-emitting element of a seventeenth aspect of the disclosure according to any one of the first to sixteenth aspects, the light-emitting layer emits light using quantum dots.

A method of manufacturing a light-emitting element according to an eighteenth aspect of the disclosure is a method of manufacturing the light-emitting element according to any one of the first to sixth aspects, the method including forming a charge function layer of the light-emitting element which includes a metal oxide, forming a base metal film on the charge function layer; and forming first metal particles and second metal particles of the light-emitting element with a metal obtained by reducing the metal oxide using the base metal film.

A method of manufacturing a light-emitting element according to a nineteenth aspect of the disclosure is a method of manufacturing the light-emitting element according to any one of the seventh to fourteenth aspects, the method including forming a charge function layer of the light-emitting element which includes a metal oxide, forming a base metal film on the charge function layer; and forming a metal structure of the light-emitting element with a metal obtained by reducing the metal oxide using the base metal film.

In a method of manufacturing a light-emitting element of a twentieth aspect of the disclosure according to the eighteenth or nineteenth aspect, at least a part of an electrode of the light-emitting element is formed using the base metal film.

In a method of manufacturing a light-emitting element of a 21st aspect of the disclosure according to any one of the eighteenth to twentieth aspects, a light-emitting layer of the light-emitting element emits light using quantum dots.

The disclosure is not limited to the embodiments described above, and various modifications can be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A light-emitting element comprising:
a light-emitting layer;
an electrode; and
a charge function layer located between the light-emitting layer and the electrode,
wherein the charge function layer includes a first metal particle located on a side of the electrode of the charge function layer, and a second metal particles positioned at a location separated from the first metal particle at a distance of 5 nm or less, and
the second metal particle has a portion located closer to the light-emitting layer than a lower end of the first metal particle.

2. The light-emitting element according to claim 1, further comprising:
a metal structure including a plurality of metal particles including at least the first metal particle and the second metal particle,
wherein a maximum value of a distance between any two adjacent particles in the plurality of metal particles is 5 nm or less.

3. The light-emitting element according to claim 2,
wherein a width including the second metal particle in the metal structure is smaller than a width including the first metal particle.

4. The light-emitting element according to claim 2,
wherein the metal particles are separated from the light-emitting layer.

5. The light-emitting element according to claim 1,
wherein the first metal particle and the second metal particle include the same metal element.

6. The light-emitting element according to claim 1,
wherein the first metal particle is in contact with the electrode.

7. A light-emitting element comprising:
a light-emitting layer;
an electrode; and
a charge function layer located between the light-emitting layer and the electrode,
wherein the charge function layer includes at least one metal structure, and
the metal structure includes a first conductor portion located on a side of the electrode of the charge function layer, and a second conductor portion protruding from the first conductor portion toward the light-emitting layer.

8. The light-emitting element according to claim 7,
wherein the first conductor portion and the second conductor portion include the same metal element.

9. The light-emitting element according to claim 7,
wherein a width of the first conductor portion is larger than a width of the second conductor portion.

10. The light-emitting element according to claim 7,
wherein the metal structure is separated from the light-emitting layer.

11. (canceled)

12. The light-emitting element according to claim 7,
wherein the charge function layer includes a plurality of metal structures, and includes a first cross-section along a thickness direction of the charge function layer and including at least two of the plurality of metal structures, and a second cross-section along the thickness direction of the charge function layer and perpendicular to the first cross-section and including at least two of the plurality of metal structures.

13. The light-emitting element according to claim 12,
wherein a distance between two adjacent metal structures among the plurality of metal structures is 100 nm or more.

14. The light-emitting element according to claim 13,
wherein, in each of the plurality of metal structures, the first conductor portion has a width of 100 nm or less, and the second conductor portion has a width of 40 nm or less.

15. The light-emitting element according to claim 1,
wherein the charge function layer includes a plurality of metal nanoparticles, and
a particle size distribution of the plurality of metal nanoparticles has a median value of 4 nm or more and 6 nm or less, a minimum value of 1 nm or more, and a maximum value of 30 nm or less.

16. The light-emitting element according to claim 15,
wherein each of the plurality of metal nanoparticles is any one of a Group 1 element, a Group 4 element, a Group 6 element, and a Group 12 element.

17. The light-emitting element according to claim 1,
wherein the light-emitting layer emits light using quantum dots.

18. A method of manufacturing the light-emitting element according to claim 1, the method comprising:
forming a charge function layer of the light-emitting element, the charge function layer including a metal oxide;
forming a base metal film on the charge function layer; and
forming a first metal particles and a second metal particle of the light-emitting element with a metal obtained by reducing the metal oxide using the base metal film.

19. A method of manufacturing the light-emitting element according to claim 7, the method comprising:
forming a charge function layer of the light-emitting element, the charge function layer including a metal oxide;
forming a base metal film on the charge function layer; and
forming a metal structure of the light-emitting element with a metal obtained by reducing the metal oxide using the base metal film.

20. The method of manufacturing the light-emitting element according to claim 18,
wherein at least a part of an electrode of the light-emitting element is formed using the base metal film.

21. The method of manufacturing the light-emitting element according to claim 18,
wherein a light-emitting layer of the light-emitting element emits light using quantum dots.
